(19) United States
(12) Patent Application Publication
(10) Pub. No.: US 2026/0052921 A1
(43) Pub. Date: Feb. 19, 2026

(54) DEEP TRENCH ISOLATION ETCHING

(71) Applicant: Applied Materials, Inc., Santa Clara, CA (US)

(72) Inventors: Han Wang, Sunnyvale, CA (US); Gene H. Lee, San Jose, CA (US)

(73) Assignee: Applied Materials, Inc., Santa Clara, CA (US)

(21) Appl. No.: 19/289,223

(22) Filed: Aug. 4, 2025

Related U.S. Application Data
(60) Provisional application No. 63/682,591, filed on Aug. 13, 2024.

(51) Int. Cl. H01L 21/3065; C09K 13/08

(52) U.S. Cl. CPC H01L 21/3065; C09K 13/08

(57) ABSTRACT

Methods of manufacturing semiconductor devices are described. A film stack on a substrate is exposed to a mixture of chlorine (Cl₂), hydrogen bromide (HBr), oxygen (O₂), and a fluorine-containing hydrocarbon to etch an opening in the film stack. The fluorine-containing hydrocarbon may have a general formula (I) CxHyFz wherein x is an integer in a range of from 1 to 4, y is an integer in a range of from 0 to 8, and z is an integer in a range of from 1 to 8. The film stack may additionally be exposed to etch cycles of a plasma where the plasma can be turned off periodically.

### CROSS-REFERENCE TO RELATED APPLICATIONS

This application claims priority to U.S. Provisional Application No. 63/682,591, filed Aug. 13, 2024, the entire disclosure of which is hereby incorporated by reference herein.

### TECHNICAL FIELD

Embodiments of the present disclosure pertain to the field of semiconductor devices and semiconductor device manufacturing. More particularly, embodiments of the disclosure provide methods of increasing etch selectivity in the manufacture of three-dimensional (3D) dynamic random-access memory devices.

### BACKGROUND

Electronic devices, such as personal computers, workstations, computer servers, mainframes, and other computer related equipment such as printers, scanners and hard disk drives use memory devices that provide substantial data storage capability, while incurring low power consumption. There are two major types of random-access memory cells, dynamic and static, which are well-suited for use in electronic devices. Dynamic random-access memories (DRAMs) can be programmed to store a voltage which represents one of two binary values but require periodic reprogramming or “refreshing” to maintain this voltage for more than very short periods of time. Static random-access memories (SRAM) are so named because they do not require periodic refreshing.

DRAM memory circuits are manufactured by replicating millions of identical circuit elements, known as DRAM cells, on a single semiconductor wafer. Each DRAM cell is an addressable location that can store one bit (binary digit) of data. In its most common form, a DRAM cell consists of two circuit components: a field effect transistor (FET) and a capacitor.

The manufacturing of a DRAM cell includes the fabrication of a transistor, a capacitor, and three contacts: one each to the bitline, the wordline, and the reference voltage. DRAM manufacturing is a highly competitive business. There is continuous pressure to decrease the size of individual cells and to increase memory cell density to allow more memory to be squeezed onto a single memory chip, especially for densities greater than 256 Megabits. Limitations on cell size reduction include the passage of both active and passive wordlines through the cell, the size of the cell capacitor, and the compatibility of array devices with nonarray devices.

Deep trench isolation of silicon (Si)/silicon germanium (SiGe) pairs in DRAM devices is a fundamental process step of 3D DRAM manufacturing. Tetraethoxysilane (TEOS) is traditionally used as a hardmask material for deep trench isolation applications, and a mixture of chlorine (Cl₂), hydrogen bromide (HBr), and oxygen (O₂) chemistry may be used during etch processes. This chemistry, however, results in obstruction of the hardmask opening due to byproduct build up, reduced etch selectivity and etch profile distortions. Therefore, there is a need in the art for methods of forming memory devices that can overcome the obstruction issues during etching.

### SUMMARY

One or more embodiments of the disclosure are directed to methods of manufacturing a semiconductor device. In one or more embodiments, the method comprises: performing an etch process to etch an opening in a film stack on a substrate using a mixture of chlorine, hydrogen bromide, oxygen, and a fluorine-containing hydrocarbon.

Additional embodiments of the disclosure are directed to methods of manufacturing a semiconductor device. In one or more embodiments, the method comprises: forming a film stack on a substrate, the film stack comprising a plurality of alternating layers of a first material layer and a second material layer; and performing an etch process to etch an opening in the film stack on the substrate using a mixture of chlorine, hydrogen bromide, oxygen, and a fluorine-containing hydrocarbon.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a process flow diagram of a method for forming a semiconductor device in accordance with one or more embodiments of the disclosure;

FIG. 2 illustrates a schematic diagram of an example multi-chamber processing system according to one or more embodiments of the present disclosure;

FIG. 3A illustrates a cross-sectional view of a semiconductor device according to the prior art;

FIG. 3B illustrates a top-down view of the semiconductor device of FIG. 3A according to the prior art;

FIG. 4A illustrates a cross-sectional view of a semiconductor device according one or more embodiments of the present disclosure;

FIG. 4B illustrates a cross-sectional view of a semiconductor device according one or more embodiments of the present disclosure; and

FIG. 4C illustrates a top-down view of the semiconductor device of FIG. 4A according to one or more embodiments of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface. What a given substrate surface comprises will depend on what films are to be deposited, as well as the particular chemistry used.

As used in this specification and the appended claims, the terms “precursor”, “reactant”, “reactive gas”, and the like are used interchangeably to refer to any gaseous species that can react with the substrate surface.

In the following description, numerous specific details, such as specific materials, chemistry, dimensions of the elements, etc. are set forth in order to provide thorough understanding of one or more of the embodiments of the present disclosure. It will be apparent, however, to one of ordinary skill in the art that the one or more embodiments of the present disclosure may be practiced without these specific details. In other instances, semiconductor fabrication processes, techniques, materials, equipment, etc., have not been described in great detail to avoid unnecessarily obscuring this description. Those of ordinary skill in the art, with the included description, will be able to implement appropriate functionality without undue experimentation.

While certain exemplary embodiments of the disclosure are described and shown in the accompanying drawings, it is to be understood that such embodiments are merely illustrative and not restrictive of the current disclosure, and that this disclosure is not restricted to the specific constructions and arrangements shown and described because modifications may occur to those ordinarily skilled in the art.

As used herein, the term “dynamic random access memory” or “DRAM” refers to a memory cell that stores a datum bit by storing a packet of charge (i.e., a binary one), or no charge (i.e., a binary zero) on a capacitor. The charge is gated onto the capacitor via an access transistor and sensed by turning on the same transistor and looking at the voltage perturbation created by dumping the charge packet on the interconnect line on the transistor output. Thus, a single DRAM cell is made of one transistor and one capacitor. The DRAM device is formed of an array of DRAM cells.

Traditionally, DRAM cells have recessed high work-function metal structures in buried wordline structure. In a DRAM device, a bitline is formed in a metal level situated above the substrate, while the wordline is formed at the polysilicon gate level at the surface of the substrate. In the buried wordline (bWL), a wordline is buried below the surface of a semiconductor substrate using a metal as a gate electrode.

Briefly, with further details provided herein, the manufacture of 3D DRAM starts from silicon (Si)/silicon germanium (SiGe) superlattice stack deposition. In one or more embodiments, an isolation etch of the 3D DRAM to isolate different transistors and capacitors occurs. It is at the cell area. After the isolation etch, there will be a flowable CVD gap filling step to infill the dielectric oxide material.

The embodiments of the disclosure are described by way of the Figures, which illustrate devices (e.g., DRAM) and processes for forming DRAM devices in accordance with one or more embodiments of the disclosure. The processes shown are merely illustrative possible uses for the disclosed processes, and the skilled artisan will recognize that the disclosed processes are not limited to the illustrated applications.

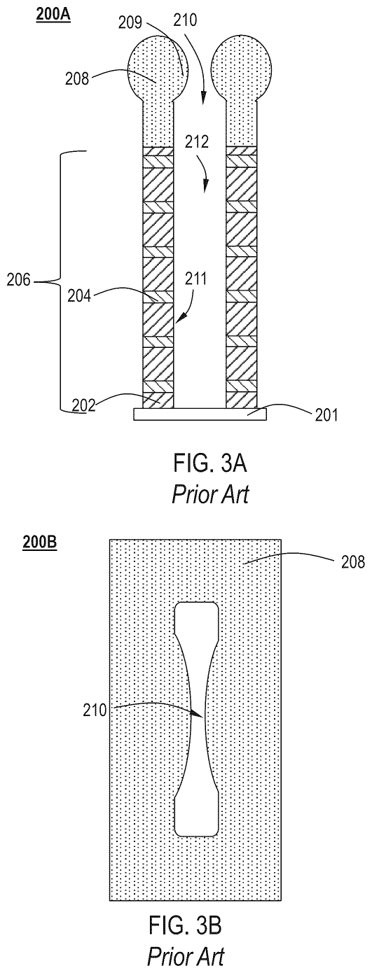

Referring to FIGS. 3A and 3B, which are according to the prior art, the deep trench isolation of the superlattice structure 206 including alternating layers of silicon (Si) 202 silicon germanium (SiGe) 204 in DRAM devices 200 is a fundamental process step of 3D DRAM manufacturing. Tetraethoxysilane (TEOS) is traditionally used as a hardmask material for deep trench isolation applications, and a mixture of chlorine (Cl₂), hydrogen bromide (HBr), and oxygen (O₂) chemistry may be used during etch processes. In one or more embodiments, the hydrogen bromide (HBr) reacts with the silicon (Si) of the superlattice structure 206 to form silicon bromide (SiBr₄). The silicon bromide (SiBr₄) then reacts with oxygen (O₂) and forms silicon oxide 208 on the top of the hardmask. This chemistry, however, results in an obstruction 209 of the deep trench 210 due to byproduct buildup of silicon oxide (SiOx) 208, reducing etch selectivity and causing etch profile distortions of the superlattice region 212 of the deep trench 210.

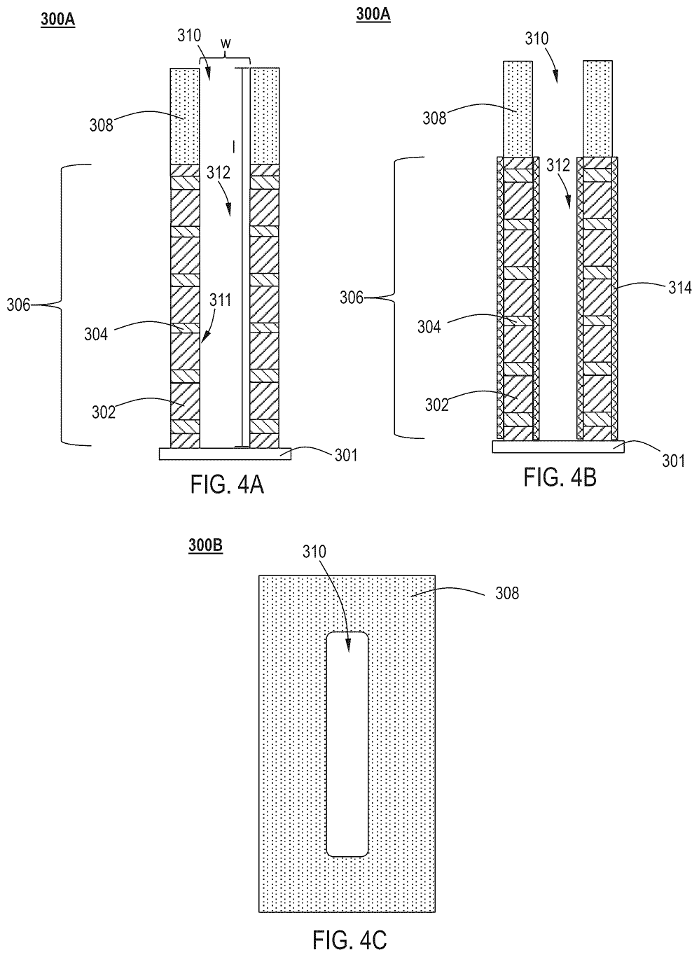

In one or more embodiments, the chemistry used during the etch process is advantageously modified to include a fluorine-containing hydrocarbon. Referring to FIGS. 4A and 4B, in one or more embodiments, the fluorine-based chemistry effectively removes any silicon oxide (SiOx) 308 that causes obstruction of the deep trench 310 and does not adversely impact the profile of superlattice structure 306 including alternating layers of silicon (Si) 302 silicon germanium (SiGe) 304 in DRAM devices 300.

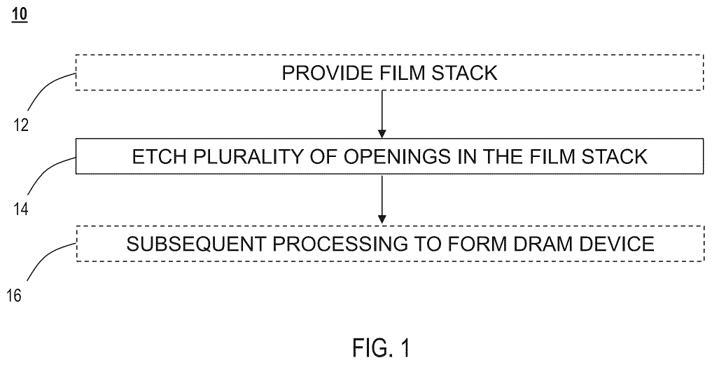

FIG. 1 is a process flow diagram of a method 10 of forming a semiconductor device according to one or more implementations of the present disclosure. FIGS. 4A and 4B are a cross-sectional views of a portion of the semiconductor device 300A corresponding to various states of the method 10. FIG. 4C is a top-down view of a portion of the semiconductor device illustrated in FIG. 4B. It should be understood that FIGS. 4A through 4C illustrate only partial schematic views of the semiconductor device 300, and the semiconductor device 300 may contain any number of sections and additional materials having aspects as illustrated in the figures.

It should also be noted although the method steps illustrated in FIG. 1 are described sequentially, other process sequences that include one or more method steps that have been omitted and/or added, and/or has been rearranged in another desirable order, fall within the scope of the embodiments of the disclosure provided herein.

Method 10 may include one or more operations prior to the initiation of the stated method operations, including front end processing, deposition, etching, polishing, cleaning, or any other operations that may be performed prior to the described operations. The method may include a number of optional operations as denoted in the figure, which may or may not specifically be associated with the method according to the present technology. For example, many of the operations are described in order to provide a broader scope of the structural formation process, but are not critical to the technology, or may be performed by alternative methodology as will be discussed further below.

In the method 10 of one or more embodiments, at operation 12, a memory or film stack is provided. As used in this manner, the term “provided” means that the memory or film stack is made available for processing. Referring to FIGS. 4A through 4C, some embodiments of the disclosure are directed to memory devices 300A, 300B. In some embodiments, the film stack forms a superlattice structure. FIGS. 4A and 4B illustrate a superlattice structure 306, which may be on the surface of a substrate 301. The substrate 301 can be any suitable substrate surface as will be understood by the skilled artisan. The film stack or superlattice structure 306, as illustrated in FIGS. 4A and 4B, comprises alternating layers of a first material 302 (e.g., silicon (Si)) and a second material 304 (e.g., silicon germanium (SiGe)). The number of layers illustrated in the film stack or superlattice structure 306 is merely representative of one possible configuration and should not be taken as limiting the scope of the disclosure.

The substrate 301 can be any suitable material known to the skilled artisan. As used in this specification and the appended claims, the term “substrate” refers to a surface, or portion of a surface, upon which a process acts. It will also be understood by those skilled in the art that reference to a substrate can refer to only a portion of the substrate unless the context clearly indicates otherwise. Additionally, reference to depositing on a substrate can mean both a bare substrate and a substrate with one or more films or features deposited or formed thereon.

In some embodiments, the substrate 301 may be a bulk semiconductor substrate. As used herein, the term “bulk semiconductor substrate” refers to a substrate in which the entirety of the substrate is comprised of a semiconductor material. The bulk semiconductor substrate may comprise any suitable semiconducting material and/or combinations of semiconducting materials for forming a semiconductor structure. For example, the semiconducting layer may comprise one or more materials such as crystalline silicon (e.g., Si<100> or Si<111>), silicon oxide, strained silicon, silicon germanium, doped or undoped polysilicon, doped or undoped silicon wafers, patterned or non-patterned wafers, doped silicon, germanium, gallium arsenide, or other suitable semiconducting materials. In some embodiments, the semiconductor material is silicon (Si). In one or more embodiments, the semiconductor substrate comprises a semiconductor material, e.g., silicon (Si), carbon (C), germanium (Ge), silicon germanium (SiGe), germanium tin (GeSn), other semiconductor materials, or any combination thereof. In one or more embodiments, the substrate 301 comprises one or more of silicon (Si), germanium (Ge), gallium (Ga), arsenic (As), or phosphorus (P). Although a few examples of materials from which the substrate may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

In some embodiments, the semiconductor material may be a doped material, such as n-doped silicon (n-Si), or p-doped silicon (p-Si). In some embodiments, the substrate 301 may be doped using any suitable process such as an ion implantation process. As used herein, the term “n-type” refers to semiconductors that are created by doping an intrinsic semiconductor with an electron donor element during manufacture. The term n-type comes from the negative charge of the electron. In n-type semiconductors, electrons are the majority carriers and holes are the minority carriers. As used herein, the term “p-type” refers to the positive charge of a well (or hole). As opposed to n-type semiconductors, p-type semiconductors have a larger hole concentration than electron concentration. In p-type semiconductors, holes are the majority carriers and electrons are the minority carriers. In one or more embodiments, the present technology may provide improved mobility in both p-and n-type semiconductors. In one or more embodiments, however, p-type semiconductors may experience further improved hole mobility.

In one or more embodiments, the film stack or superlattice structure 306 may have any number of alternating first material layers 302 and second material layers 304. In one or more embodiments, the film stack or superlattice structure 306 comprises a plurality of alternating first material layers 302 and second material layers 304. In some embodiments, the film stack or superlattice structure 306 comprises greater than 100 pairs of alternating first material layers 302 and second material layers 304.

In some embodiments, the first material layers 302, second material layers 304, and sacrificial layers (if included) are made of materials that are etch selective relative to each other. In some embodiments, the first material layers 302 comprise silicon (Si) and the second material layers 304 comprise silicon germanium (SiGe). In some embodiments, the film stack or superlattice structure 306 comprises alternating layers of oxides and polysilicon, nitrides and polysilicon, or oxides and nitrides.

In one or more embodiments, the first material layers 302 and second material layers 304 can be deposited by any suitable technique known to the skilled artisan. For example, the first material layers 302 and second material layers 304 of some embodiments, are deposited by one or more of atomic layer deposition (ALD) chemical vapor deposition (CVD), physical vapor deposition (PVD) or epitaxy.

“Atomic layer deposition” or “cyclical deposition” as used herein refers to the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A, e.g., aluminum precursor) is pulsed into the reaction zone followed by a first time-delay. Next, a second precursor or compound B (e.g., oxidant) is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

As used herein, “chemical vapor deposition” refers to a process in which a substrate surface is exposed to precursors and/or co-reagents simultaneously or substantially simultaneously. As used herein, “substantially simultaneously” refers to either co-flow or where there is overlap for a majority of exposures of the precursors.

Plasma enhanced chemical vapor deposition (PECVD) is widely used to deposit thin films due to cost efficiency and film property versatility. In a PECVD process, for example, a hydrocarbon source, such as a gas-phase hydrocarbon or a vapor of a liquid-phase hydrocarbon that have been entrained in a carrier gas, is introduced into a PECVD chamber. A plasma-initiated gas, typically helium, is also introduced into the chamber. Plasma is then initiated in the chamber to create excited CH-radicals. The excited CH-radicals are chemically bound to the surface of a substrate positioned in the chamber, forming the desired film thereon. Embodiments described herein in reference to a PECVD process can be carried out using any suitable thin film deposition system. Any apparatus description described herein is illustrative and should not be construed or interpreted as limiting the scope of the embodiments described herein.

The individual alternating layers of the film stack may be formed to any suitable thickness. In some embodiments, the thickness of each second material layer 304 is approximately equal. In one or more embodiments, alternating first material layers 302 are about two to ten times thicker than the second material layers 304.

Referring to FIG. 1 and FIGS. 4A and 4B, at operation 14, the semiconductor device is subjected to a deep trench isolation etch process to form at least one deep trench opening 310. The opening 310 allows access to the film stack or superlattice structure 306. The opening 310 can be formed by any suitable technique known to the skilled artisan. In some embodiments, the openings 310 is formed by applying a hardmask material, e.g., tetraethoxysilane (TEOS) or the like, over the substrate and performing a directional etch through the hardmask material.

In one or more embodiments, the opening 310 is formed between adjacent superlattice structures 306 and includes at least one sidewall 311. In one or more embodiments, the opening 310 may have any suitable aspect ratio. As used herein, the term “aspect ratio” refers to the ratio of the depth (or height) of the opening to the width of the opening. In some embodiments, the aspect ratio of the opening 310 is greater than or equal to about 50:1, 100:1, 200:1, 250:1, 300:1, 350:1 or 400:1. In one or more embodiments, the aspect ratio is greater than 200:1. In some embodiments, the opening 310 has a first critical dimension (CD), or length, l, in a range of from >1 nm to 1000 nm, including in a range of from 100 nm to 800 nm. In one or more embodiments, the opening 310 has a second critical dimension, or width w, in a range of from >1 nm to 100 nm, including in a range of from 20 nm to 80 nm.

In one or more embodiments, a fluorine containing hydrocarbon is added into a mixture of chlorine (Cl₂), hydrogen bromide (HBr), and oxygen (O₂) to etch the film stack or superlattice structure 306. The fluorine-containing hydrocarbon may be any suitable compound known to the skilled artisan.

In one or more embodiments, the fluorine-containing hydrocarbon has a general formula (I): CₓH_{y}F_{z} where x is the number of carbon atoms and is an integer in a range of from 1 to 4, y is the number of hydrogen atoms and is an integer in a range of from 0 to 8, and z is the number of fluorine atoms and is an integer in a range of from 1 to 8.

In some embodiments, the fluorine-containing hydrocarbon may comprise one or more of fluoromethane (CH₃F), difluoromethane (CH₂F₂), carbon tetrafluoride (CF₄), trifluoromethane (CHF₃), tetrafluoroethane (C₂H₂F₄), hexafluoropropene (C₃F₆), hexafluoro-1,3-butadiene (C₄F₆), octafluorocyclobutate (C₄F₈), and the like.

In one or more embodiments, the mixture may contain in a range of from 80 wt. % to 99 wt. % of chlorine (Cl₂), hydrogen bromide (HBr), and oxygen (O₂), and in a range of from 1 wt. % to 20 wt. % fluorine-containing hydrocarbon, based on the total weight of the chemistry mixture.

Without intending to be bound by theory, it is thought that because fluorine (F) has a lower atomic mass than chlorine (Cl), fluorine (F) will react with the obstructing silicon oxide (SiOx) 308 at the hardmask area and will not be able to extend into the superlattice structure region 312 of the opening 310. Accordingly, in one or more embodiments, the addition of the fluorine-containing hydrocarbon to the etch chemistry advantageously reduces the silicon oxide (SiOx) obstruction without damaging the profile of the superlattice structure 306. In one or more embodiments, the addition of the fluorine-containing hydrocarbon to the etch chemistry advantageously improves the etch selectivity of the deep trench isolation process.

As illustrated in FIG. 4B, in one or more embodiments, the byproduct of the etching process is a hydrocarbon-based polymer 314, which can serve as additional sidewall 311 passivation for profile control of the superlattice structure 306. In one or more embodiments, in addition to passivation of the sidewall 311, the etching process also advantageously provides for in situ clogging removal.

Further, in one or more embodiments, advanced plasma pulsing may further reduce the obstruction of silicon oxide (SiOx) observed in the device (see FIGS. 3A and 3B). In one or more embodiments, during the etch process, the plasma can be turned off periodically. In one or more embodiments, there could be from 1 etch cycle per second up to 5000 etch cycles per second. In one or more embodiments, if no plasma radicals are formed, no silicon oxide (SiOx) byproduct is deposited. In one or more embodiments, the processing chamber is maintained at high vacuum and prior silicon oxide (SiOx) byproduct will be pumped out.

In one or more embodiments, when compared to the conventional chlorine (Cl₂), hydrogen bromide (HBr), oxygen (O₂) chemistry where the plasma is always turned on, silicon oxide (SiOx) obstruction at the top of the opening 310 is removed in situ. Additionally, in one or more embodiments, there may advantageously be higher throughputs with a shorter post-etch cleaning, or, even, no post-etch cleaning may be necessary. Accordingly, in one or more embodiments, the profile of the superlattice structure region 312 is preserved, which is beneficial for subsequent downstream processing, such as during gap fill.

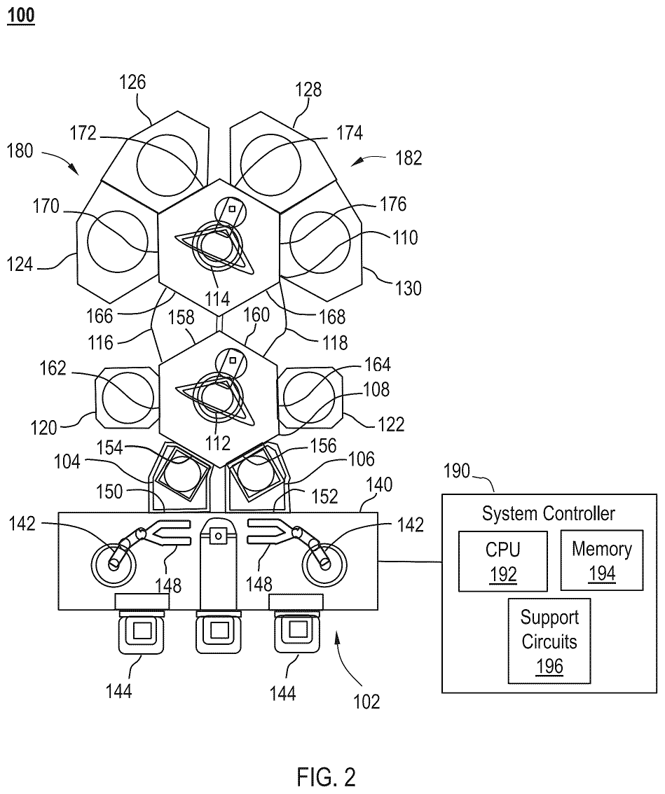

FIG. 2 is a schematic top-view diagram of an example of a multi-chamber processing system 100 according to some examples of the present disclosure. The processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, wafers in the processing system 100 can be processed in and transferred between the various chambers without exposing the wafers to an ambient environment exterior to the processing system 100 (e.g., an atmospheric ambient environment such as may be present in a fab). In other embodiments, it is desired that the wafers be exposed to the ambient environment between processing steps, as will be detailed below.

In one or more embodiments, the wafers can be processed in and transferred between the various chambers in a low pressure (e.g., less than or equal to about 300 Torr) or vacuum environment without breaking the low pressure or vacuum environment between various processes performed on the wafers in the processing system 100. Accordingly, the processing system 100 may provide an integrated solution for some processing of wafers. Any suitable processing system known to the skilled artisan may be used.

In the illustrated example of FIG. 2, the factory interface 102 includes a docking station 140 and factory interface robots 142 to facilitate transfer of wafers. The docking station 140 is configured to accept one or more front opening unified pods (FOUPs) 144. In some examples, each factory interface robot 142 generally comprises a blade 148 disposed on one end of the respective factory interface robot 142 configured to transfer the wafers from the factory interface 102 to the load lock chambers 104, 106.

The load lock chambers 104, 106 have respective ports 150, 152 coupled to the factory interface 102 and respective ports 154, 156 coupled to the transfer chamber 108. The transfer chamber 108 further has respective ports 158, 160 coupled to the holding chambers 116, 118 and respective ports 162, 164 coupled to processing chambers 120, 122. Similarly, the transfer chamber 110 has respective ports 166, 168 coupled to the holding chambers 116, 118 and respective ports 170, 172, 174, 176 coupled to processing chambers 124, 126, 128, 130. The ports 154, 156, 158, 160, 162, 164, 166, 168, 170, 172, 174, 176 can be, for example, slit valve openings with slit valves for passing wafers therethrough by the transfer robots 112, 114 and for providing a seal between respective chambers to prevent a gas from passing between the respective chambers. Generally, any port is open for transferring a wafer therethrough. Otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 142 transfers a wafer from a FOUP 144 through a port 150 or 152 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the wafer between, for example, the atmospheric environment of the factory interface 102 and the low pressure or vacuum environment of the transfer chamber 108.

With the wafer in the load lock chamber 104 or 106 that has been pumped down, the transfer robot 112 transfers the wafer from the load lock chamber 104 or 106 into the transfer chamber 108 through the port 154 or 156. The transfer robot 112 is then capable of transferring the wafer to and/or between any of the processing chambers 120, 122 through the respective ports 162, 164 for processing and the holding chambers 116, 118 through the respective ports 158, 160 for holding to await further transfer. Similarly, the transfer robot 114 is capable of accessing the wafer in the holding chamber 116 or 118 through the port 166 or 168 and is capable of transferring the wafer to and/or between any of the processing chambers 124, 126, 128, 130 through the respective ports 170, 172, 174, 176 for processing and the holding chambers 116, 118 through the respective ports 166, 168 for holding to await further transfer. The transfer and holding of the wafer within and among the various chambers can be in the low pressure or vacuum environment provided by the gas and pressure control system.

The processing chambers 120, 122, 124, 126, 128, 130 can be any appropriate chamber for processing a wafer. In some embodiments, the processing chamber 120 can be capable of performing an annealing process, the processing chamber 122 can be capable of performing a cleaning process, and the processing chambers 124, 126, 128, 130 can be capable of performing epitaxial growth processes. In some examples, the processing chamber 122 can be capable of performing a cleaning process, the processing chamber 120 can be capable of performing an etch process, and the processing chambers 124, 126, 128, 130 can be capable of performing respective epitaxial growth processes. The processing chamber 122 may be any suitable preclean chamber known to the skilled artisan. The processing chamber 120 may be any suitable, etch chamber known to the skilled artisan.

A system controller 190 is coupled to the processing system 100 for controlling the processing system 100 or components thereof. For example, the system controller 190 may control the operation of the processing system 100 using a direct control of the chambers 104, 106, 108, 116, 118, 110, 120, 122, 124, 126, 128, 130 of the processing system 100 or by controlling controllers associated with the chambers 104, 106, 108, 116, 118, 110, 120, 122, 124, 126, 128, 130. In operation, the system controller 190 enables data collection and feedback from the respective chambers to coordinate performance of the processing system 100.

The system controller 190 generally includes a central processing unit (CPU) 192, memory 194, and support circuits 196. The CPU 192 may be one of any form of a general-purpose processor that can be used in an industrial setting. The memory 194, or non-transitory computer-readable medium, is accessible by the CPU 192 and may be one or more of memory such as random-access memory (RAM), read only memory (ROM), floppy disk, hard disk, or any other form of digital storage, local or remote. The support circuits 196 are coupled to the CPU 192 and may comprise cache, clock circuits, input/output subsystems, power supplies, and the like. The various methods disclosed herein may generally be implemented under the control of the CPU 192 by the CPU 192 executing computer instruction code stored in the memory 194 (or in memory of a particular process chamber) as, for example, a software routine. When the computer instruction code is executed by the CPU 192, the CPU 192 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A method of manufacturing a semiconductor device, the method comprising:
performing an etch process to etch an opening in a film stack on a substrate using a mixture of chlorine, hydrogen bromide, oxygen, and a fluorine-containing hydrocarbon.

2. The method of claim 1, wherein the fluorine-containing hydrocarbon has a general formula (I) CxHyFz wherein x is an integer in a range of from 1 to 4, y is an integer in a range of from 0 to 8, and z is an integer in a range of from 1 to 8.

3. The method of claim 1, wherein the fluorine-containing hydrocarbon comprises one or more of fluoromethane (CH₃F), difluoromethane (CH₂F₂), carbon tetrafluoride (CF₄), trifluoromethane (CHF₃), tetrafluoroethane (C₂H₂F₄), hexafluoropropene (C₃F₆), hexafluoro-1,3-butadiene (C₄F₆), octafluorocyclobutate (C₄F₈), and the like.

4. The method of claim 1, wherein the mixture contains in a range of from 80 wt. % to 99 wt. % of chlorine (Cl₂), hydrogen bromide (HBr), and oxygen (O₂), and in a range of from 1 wt. % to 20 wt. % fluorine-containing hydrocarbon, based on the total weight of the mixture.

5. The method of claim 1, wherein the opening comprises a sidewall of the film stack and, after exposure to the mixture, the sidewall comprises a hydrocarbon-based polymer.

6. The method of claim 1, wherein the etch process comprises forming a plasma from the mixture and exposing the film stack to the plasma.

7. The method of claim 6, wherein the film stack is exposed to the plasma in a range of from 1 etch cycle per second to 5000 etch cycles per second.

8. The method of claim 1, wherein the film stack comprises a plurality of alternating layers of a first material layer and a second material layer on the substrate.

9. The method of claim 8, wherein the first material layer comprises silicon (Si).

10. The method of claim 8, wherein the second material layer comprises silicon germanium (SiGe).

11. The method of claim 1, wherein the opening has an aspect ratio greater than 100:1.

12. A method of manufacturing a semiconductor device, the method comprising:
forming a film stack on a substrate, the film stack comprising a plurality of alternating layers of a first material layer and a second material layer; and
performing an etch process to etch an opening in the film stack on the substrate using a mixture of chlorine, hydrogen bromide, oxygen, and a fluorine-containing hydrocarbon.

13. The method of claim 12, wherein the fluorine-containing hydrocarbon has a general formula (I) CxHyFz wherein x is an integer in a range of from 1 to 4, y is an integer in a range of from 0 to 8, and z is an integer in a range of from 1 to 8.

14. The method of claim 12, wherein the fluorine-containing hydrocarbon comprises one or more of fluoromethane (CH₃F), difluoromethane (CH₂F₂), carbon tetrafluoride (CF₄), trifluoromethane (CHF₃), tetrafluoroethane (C₂H₂F₄), hexafluoropropene (C₃F₆), hexafluoro-1,3-butadiene (C₄F₆), octafluorocyclobutate (C₄F₈), and the like.

15. The method of claim 12, wherein the mixture contains in a range of from 80 wt. % to 99 wt. % of chlorine (Cl₂), hydrogen bromide (HBr), and oxygen (O₂), and in a range of from 1 wt. % to 20 wt. % fluorine-containing hydrocarbon, based on the total weight of the mixture.

16. The method of claim 12, wherein the first material layer comprises silicon (Si) and the second material layer comprises silicon germanium (SiGe).

17. The method of claim 12, wherein the plurality of alternating layers of the first material layer and the second material layer comprise a superlattice structure.

18. The method of claim 12, wherein the opening has an aspect ratio greater than 10:1.

19. The method of claim 12, wherein the etch process comprises forming a plasma from the mixture and exposing the film stack to the plasma in a range of from 1 etch cycle per second to 5000 etch cycles per second.

20. The method of claim 12, wherein the opening comprises a sidewall of the film stack and, after exposure to the mixture, the sidewall comprises a hydrocarbon-based polymer.
